(19) United States
(12) Patent Application Publication
(10) Pub. No.: US 2018/0077792 A1
(43) Pub. Date: Mar. 15, 2018

(54) REACTOR, CONNECTION MEMBER, BOARD MODULE, AND ELECTRIC DEVICE

(71) Applicant: OMRON Corporation, Kyoto-shi, KYOTO (JP)

(72) Inventors: Takashi HORIE, Kyoto-shi (JP); Haruhisa YAMANA, Moriyama-shi (JP)

(73) Assignee: OMRON Corporation, Kyoto-shi, KYOTO (JP)

(21) Appl. No.: 15/553,384

(22) PCT Filed: Jan. 12, 2016
(86) PCT No.: PCT/JP2016/050713

§ 371 Date: Aug. 24, 2017

(30) Foreign Application Priority Data
Mar. 10, 2015 (JP) 2015-047142

(51) Int. Cl. H05K 1/02; H01F 27/29; H01F 27/06; H05K 1/14; H01F 27/24; H01F 27/40

(52) U.S. Cl. CPC H05K 1/0233; H01F 27/29; H01F 27/06; H05K 1/142; H01F 27/24; H01F 27/2876; H05K 2201/10053; H05K 2201/1003; H05K 1/0203; H05K 2201/066; H01F 27/40

(57) ABSTRACT

A reactor includes a winding, a magnetic core in the winding, and a connection member extending from the winding and electrically connecting with an electronic component, and being at least partially spiral between the winding and the electronic component. The winding and the connection member are formed from a single conductive member. The connection member includes a first spiral portion that is at least partially spiral and extends from a first end of the winding, and a second spiral portion that is at least partially spiral and extends from a second end of the winding. A spiral of the first spiral portion and a spiral of the second spiral portion may face each other.

### FIELD

The present invention relates to a connection member, a reactor, a board module, and an electric device.

### BACKGROUND

A lead wire is used to interconnect boards or a board and an electric circuit as described in Patent Literature 1.

### Patent Literature 1: Japanese Unexamined Patent Application Publication No. 2012-164878

### SUMMARY

### Technical Problem

The lead wire includes a plurality of connection points between a terminal and a wire. A relatively large pulse current flowing through the lead wire can generate radiation noise at such connection points of the lead wire. Thus, the lead wire may have fewer connection points.

### Solution to Problem

A reactor according to one aspect of the present invention includes a winding, a magnetic core included in the winding, and a connection member extending from the winding and electrically connecting with an electronic component, and being at least partially spiral between the winding and the electronic component.

The winding and the connection member are formed from a single conductive member.

In the above reactor, the single conductive member may be a single rod or a single plate.

In the above reactor, the electronic component may be a board, and the connection member may have an end directly fixed to the board.

In the above reactor, the electronic component may be a board, and the connection member may have an end directly fixed to a terminal block on the board.

In the above reactor, the connection member may include a first spiral portion that is at least partially spiral and extends from a first end of the winding, and a second spiral portion that is at least partially spiral and extends from a second end of the winding. A spiral of the first spiral portion and a spiral of the second spiral portion may face each other.

In the above reactor, the spiral of the first spiral portion and the spiral of the second spiral portion may have the same shape.

A board module according to one aspect of the present invention includes the above reactor, and a board that is the electronic component electrically connected to the reactor.

In the board module according to the above aspect, the board may include a switch that inputs a pulse current into the reactor.

An electric device according to one aspect of the present invention includes the above board module, and a housing including a first fixing member to which the reactor is fixed, and a second fixing member to which the board is fixed.

A connection member according to one aspect of the present invention is a connection member for electrically connecting a first electronic component and a second electronic component. The connection member is formed from a single conductive member. The connection member includes a first end that is electrically connected to the first electronic component, a second end that is electrically connected to the second electronic component, and a spiral portion arranged between the first end and the second end.

In the above connection member, the conductive member may be a single rod or a single plate.

In the above connection member, the first electronic component may be a first board, and the first end may be directly fixed to the first board.

In the above connection member, the first electronic component may be a first board, and the first end may be directly fixed to a terminal block on the first board.

In the above connection member, the second electronic component may be a second board, and the second end may be directly fixed to the second board.

In the connection member, the second electronic component may be a second board, and the second end may be directly fixed to a terminal block on the second board.

A board module according to one aspect of the present invention includes the above connection member, a first board that is the first electronic component including a first electric circuit, and a second board that is the second electronic component including a second electric circuit electrically connected to the first electric circuit with the connection member.

In the above board module, at least one of the first electric circuit and the second electric circuit may include a switch, and the connection member may transmit a pulse current output from the switch between the first board and the second board.

In the above board module, at least one of the first electric circuit and the second electric circuit may include a noise filter.

An electric device according to one aspect of the present invention includes the above board module, and a housing including a first fixing member to which the first board is fixed, and a second fixing member to which the second board is fixed.

The features of the present invention listed above are not exhaustive. Sub-combinations of the features described above can also fall within the scope of the present invention.

### BRIEF DESCRIPTION OF THE DRAWINGS

FIG. 1 is an external perspective view of a board module according to one embodiment.

FIG. 2 is an exploded perspective view of a board module according to another embodiment.

FIG. 3 is a perspective view of a reactor connected to a board.

FIG. 4 is a side view of the reactor connected to the board in one example.

### DETAILED DESCRIPTION

Embodiments of the present invention will now be described. The embodiments described below do not intend to limit the present invention defined by the claims. The features described in the embodiments and their combinations may not be essential for the present invention.

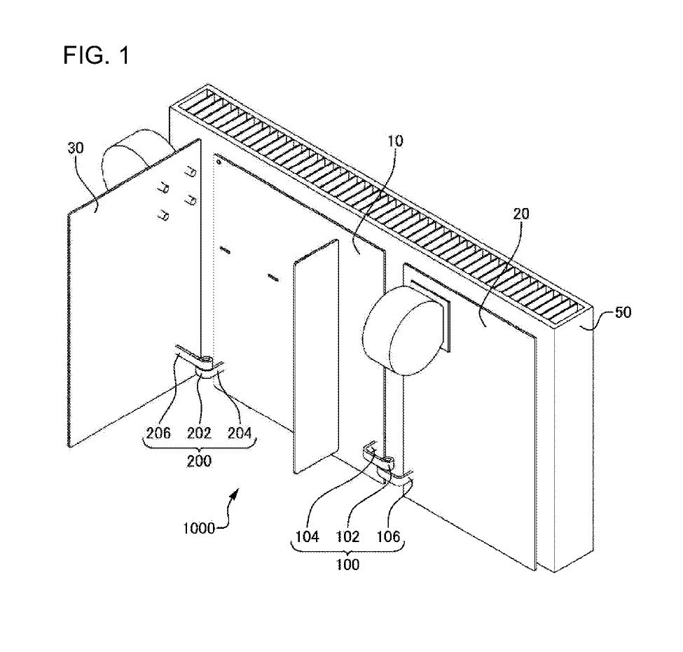

FIG. 1 is an external perspective view of a board module 1000 according to one embodiment of the present invention. The board module 1000 includes boards 10, 20, and 30, and connection members 100 and 200. Each of the boards 10, 20, and 30 includes an electric circuit. The electric circuit includes, for example, a switch, a reactor, and a noise filter. The switch may be a power module, such as an insulated gate bipolar transistor (IGBT) module or a power metal-oxide-semiconductor field-effect transistor (MOSFET) module. The boards 10 and 20 may be fixed to a heat sink 50, which is an example of a fixing member. The board 30 may be fixed to the heat sink 50 and also to an inner wall of a housing accommodating the board module with, for example, a pillar. The inner wall of the housing is another example of the fixing member.

The board module 1000 may be mounted on an electric device through which a relatively large current (e.g., 1 A or larger) can flow. The board module 1000 may be mounted on an electric device through which a pulse current flows when switched using a switch. The electric device may be, for example, a power converter such as a power conditioner, a motor driver, or a power supply.

The connection member for electrically connecting boards may typically be a lead wire. The lead wire is produced by crimping terminals, such as round terminals or Y terminals, at both ends of a wire. When a relatively large pulse current flows through the lead wire, radiation noise occurs at joints between the wire and the terminals. Such radiation noise can affect electronic circuits mounted on the board module 1000 or other external devices.

The structure according to the present invention reduces such radiation noise by reducing the number of joints on the connection members that electrically connect electronic components including boards.

The connection member 100 electrically and mechanically connects the board 10 and the board 20 to allow transmission of a current between the boards 10 and 20. The board 10 is an example of a first electronic component and an example of a first board. The board 20 is an example of a second electronic component and an example of a second board.

For efficient transmission of a current with less energy loss, for example, the connection member 100 may have a low resistance. The resistance per unit length of the connection member 100 is determined in accordance with the amount of current to flow to reduce energy loss and heat generation. The connection member 100 preferably has a low resistance. The connection member 100 is a single conductive member made of metal, such as copper, a copper alloy, or aluminum. The conductive member may be formed from a material that does not deform without a force being applied. The conductive member may be a single rod or plate.

The connection member 100 has a first end electrically connected to the board 10, and a second end electrically connected to the board 20. The connection member 100 may have its first end mechanically and directly connected to the board 10 by soldering or other connection. The connection member 100 may also have its first end mechanically and directly connected to a terminal block on the board 10. In some embodiments, the connection member 100 may have its first end mechanically and indirectly connected to the board 10 with a terminal, such as a round terminal or a Y terminal, which are separate from the connection member 100. The connection member 100 may have its second end mechanically and directly connected to the board 20 by soldering. In some embodiments, the connection member 100 may have its second end mechanically and directly connected to a terminal block on the board 20. In some other embodiments, the connection member 100 may have its second end mechanically and indirectly connected to the board 20 with a terminal, such as a round terminal or a Y terminal, which are separate from the connection member 100.

The connection member 100 includes a spiral portion between its first and second ends. The connection member 100 may be one piece formed by deforming a single rod or plate. The connection member 100 formed in this manner can reduce the number of joints on the connection member 100, and thus can reduce radiation noise that may occur in the connection member 100.

The connection member 200 electrically and mechanically connects the board 10 and the board 30 to allow transmission of a current between the boards 10 and 30. The connection member 100 may transmit a pulse current between the boards 10 and 20. In the same manner as for the connection member 100, the connection member 200 is a single conductive member made of metal, such as copper or a copper alloy.

The connection member 100 includes a first connecting portion 104, a spiral portion 102, and a second connecting portion 106. The first connecting portion 104, the spiral portion 102, and the second connecting portion 106 are integrally formed from a single conductive member. The connection member 100 may be formed by deforming, for example, a single metallic plate, such as a copper plate, or a single metallic rod, such as a copper rod.

The first connecting portion 104 includes the first end of the connection member 100, and is electrically and mechanically connected to the board 10. The first connecting portion 104 may be directly fixed to the board 10 by soldering. The first connecting portion 104 may have, at its end, a terminal, such as a round terminal or a Y terminal, and may be directly fixed to a terminal block on the board 10 with a screw for electrical and mechanical connection to the board 10.

The spiral portion 102 extends from the first connecting portion 104. The spiral portion 102 is integral with the first connecting portion 104. The spiral portion 102 is at least partially spiral. The spiral portion 102 is a plate or a rod that is bent into at least a half-turn or a full-turn winding. The spiral portion 102 may function as an air-core coil. The second connecting portion 106 includes the second end of the connection member 100. The second connecting portion 106 extends from the spiral portion 102, which is opposite to the first connecting portion 104. The second connecting portion 106 is integral with the spiral portion 102. The second connecting portion 106 is electrically and mechanically connected to the board 20. The second connecting portion 106 may be directly fixed to the board 20 by soldering. The second connecting portion 106 may have, at its end, a terminal, such as a round terminal or a Y terminal, and may be directly fixed to the terminal block on the board 20 with a screw for electrical and mechanical connection to the board 20.

In the present embodiment, the first connecting portion 104, the spiral portion 102, and the second connecting portion 106 are integrally formed by deforming a single conductive plate or rod. The first connecting portion 104, the spiral portion 102, and the second connecting portion 106 may be integrally formed by deforming a single metallic plate or metallic rod. This structure prevents radiation noise at a joint between a terminal and a wire, which can occur with a conventional lead wire.

To pass a relatively large current, the conductive member 100 may be made of metal, such as copper. When the connection member 100 is a metallic plate or a metallic rod, the connection member 100 may need a sufficient thickness to reduce its resistance to an appropriate level. As a result, the connection member 100 can be relatively rigid. The connection member 100 is more rigid than a lead wire. The connection member 100 is also more rigid than a lead wire that is a bundle of a plurality of wires, such as thin copper wires, that are mechanically and electrically connected to each other by crimping their ends with a connecting terminal. The connection member 100 is ten or more times as rigid as this lead wire. The connection member 100 is more rigid than a lead wire having a rated voltage of 300 V or more and a maximum conductor resistance of 22.6 Ω/km per unit length, which passes, for example, a relatively large pulse current with 10 A or more.

To allow a pulse current with 30 A or more to flow through the connection member 100, for example, the first connecting portion 104, the spiral portion 102, and the second connecting portion 106 may each have a cross-sectional area of 8 mm² or more, 16 mm² or more, or 30 mm² or more. To reduce heat generated by a flowing current and to reduce energy loss, the connection member 100 may be formed from a conductive member with a lower resistance. The conductive member may be made of metal, such as copper. Such a metal, for example, brass, has a Brinell hardness of 80 to 150 (HBW). The connection member 100 may also need a sufficient length to connect boards. As described above, the structure having a large cross-sectional area, higher Young's modulus, and a sufficient length can be rigid.

The board module 1000 may be mounted in the housing. The boards 10, 20, and 30 included in the board module 1000 may be fixed to separate fixing members arranged in the housing. For example, the boards 10 and 20 may be fixed to the heat sink 50 installed in the housing. The board 30 may be fixed to the inner wall of the housing with a pillar.

The fixing members can vibrate independently of one another. When the connection member that mechanically connects boards is highly rigid, the joints between the boards and the connection member can receive a large force. This can cause connection failures or cracks at the joints between the boards and the connection member. The connection member 100 according to the present embodiment can absorb vibrations in the spiral portion 102. For the boards 10 and 20 mechanically connected with the highly rigid connection member 100 that may vibrate independently of each other, the structure can reduce failures including cracks at joints between the board 10 and the connection member 100, and between the board 20 and the connection member 100.

The connection member 200 includes a first connecting portion 204, a spiral portion 202, and a second connecting portion 206. The first connecting portion 204, the spiral portion 202, and the second connecting portion 206 are integrally formed by deforming a single conductive member as for the connection member 100. The connection member 200 may be formed by deforming, for example, a single metallic plate, such as a copper plate, or a single metallic rod, such as a copper rod, in the same manner as for the connection member 100.

For the boards 10 and 30 that may be arranged vertically, the connection member 200 according to the embodiment can electrically and mechanically connect the boards 10 and 30 by optimizing the number of windings in the spiral portion 202 and the shape of the spiral portion 202. The connection members 100 and 200 may each be covered with, for example, a resin.

In the present embodiment as described above, the connection members 100 and 200 electrically and mechanically connecting electronic components, such as boards, are each formed by deforming a single conductive rod or plate. This can reduce the number of joints between components, and thus can reduce radiation noise at such joints. The connection members 100 and 200 are each at least partially spiral. When an electronic component, such as a board, mechanically connected to the connection member 100 or the connection member 200 vibrates, the spiral portion of the connection member 100 or 200 can absorb such vibrations. This can reduce connection failures or cracks at a joint between the connection member 100 or the connection member 200 and the electronic component.

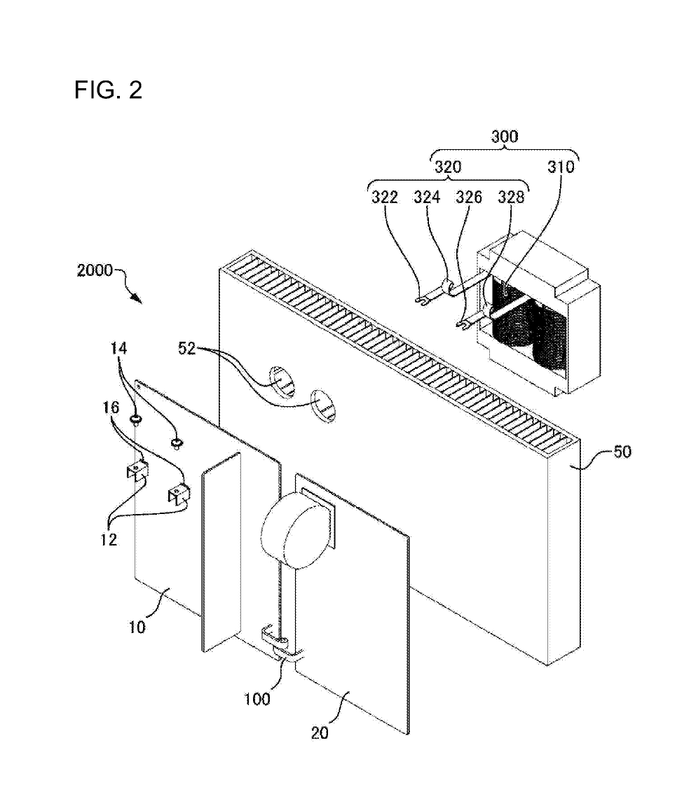

FIG. 2 is an exploded perspective view of a board module 2000 according to another embodiment. The board module 2000 may be mounted on an electric device through which a relatively large current (e.g., 10 A or more) flows. The board module 2000 may be mounted on an electric device through which a pulse current flows when switched using a switch. The electric device may be, for example, a power converter such as a power conditioner, a motor driver, or a power supply.

The board module 2000 includes a board 10, a board 20, and a reactor 300. The reactor 300 is electrically and mechanically connected to the board 10 via the heat sink 50. The board 10 is electrically connected to the board 20 via the connection member 100 described above.

A reactor through which a relatively large current flows may often have its winding coil electrically connected to a board with a lead wire. In the reactor, the lead wire and the coil are crimped and then fixed. In the same manner as for the connection between boards, the reactor is likely to have radiation noise at a joint between the coil and the lead wire. In another embodiment, the structure reduces radiation noise in a reactor connected to an electronic component, such as a board.

The reactor 300 includes a winding 310, a magnetic core included in the winding 310, and a connection member 320. The connection member 320 extends from the winding 310 and electrically connects with the board 10. The connection member 320 is at least partially spiral between the winding 310 and the board 10. The winding 310 and the connection member 320 may each have a low resistance to reduce energy loss and transmit a current efficiently. The winding 310 and the connection member 320 may each have a resistance of, for example, 20 mΩ or less, 10 mΩ or less, or 1 mΩ or less. The winding 310 and the connection member 320 are formed from a single conductive member made of metal, such as copper, a copper alloy, gold, silver, or aluminum. The conductive member may be formed from a material that is not easily deformable. The conductive member may be a single rod or plate.

The winding 310 and the connection member 320 may be one piece formed by deforming a single rod or plate. The winding 310 and the connection member 320 formed in this manner can reduce the number of joints between the winding 310 and the connection member 320, and can reduce the number of joints on the connection member 320, and can thus reduce radiation noise at such joints. The connection member 320 may have its first and second ends mechanically and directly connected to the board 10 by soldering or other connection. In some embodiments, the connection member 320 may have its first and second ends mechanically and directly connected to the terminal block on the board 10. In some other embodiments, the connection member 320 may have its first and second ends mechanically and indirectly connected to the board 10 with terminals, such as round terminals or Y terminals, which are separate from the connection member 320.

The connection member 320 includes a first connecting portion 322, a first spiral portion 324, a second connecting portion 326, and a second spiral portion 328. The first connecting portion 322 and the second connecting portion 326 may each have a terminal, such as a round terminal or a Y terminal, which allows connection to an electronic component, such as the board 10. The first spiral portion 324 extends from a first end of the winding 310, and is at least partially spiral. The second spiral portion 328 extends from a second end of the winding 310, and is at least partially spiral.

The spiral of the first spiral portion 324 and the spiral of the second spiral portion 328 may have the same shape, and may be arranged to face each other. In this arrangement, a current flowing through the first spiral portion 324 will pass through the second spiral portion 328 in a direction reverse to the direction in the first spiral portion 324. As a result, radiation noise in the first spiral portion 324 and radiation noise in the second spiral portion 328 cancel out. This structure can thus further reduce radiation noise. The first spiral portion 324 and the second spiral portion 328 facing each other can function as air-core coils, which can function as virtual filters. The first spiral portion 324 and the second spiral portion 328 each having an internal magnetic core (core) can also function as an alternating current (AC) filter or a direct current (DC) filter.

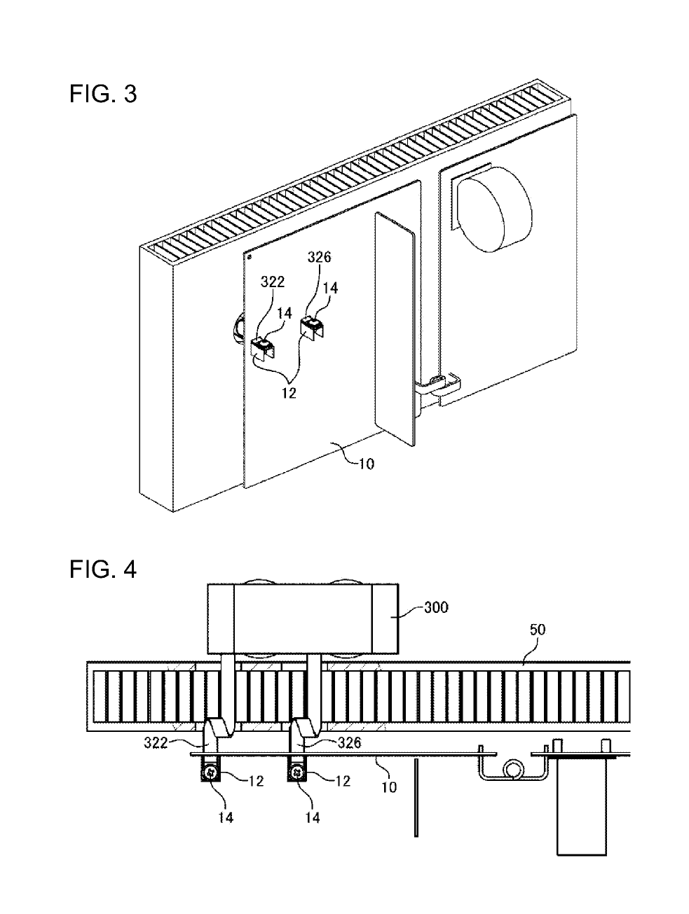

The heat sink 50 has through-holes 52 at positions facing the connection member 320 of the reactor 300. The board 10 has through-holes 16 at positions facing the connection member 320 in the reactor 300. The heat sink 50 is arranged between the reactor 300 and the board 10. The connection member 320 is passed through the through-holes 52 and the through-holes 16, and is then connected to the board 10. The board 10 includes terminal blocks 12, which are arranged at positions facing the connection member 320. The first connecting portion 322 and the second connecting portion 326 are directly fixed to the terminal blocks 12 with screws 14 as shown in FIGS. 3 and 4.

The above embodiment describes an example in which the connection member 320 is electrically and mechanically connected to the board 10 with the terminal blocks 12. In some embodiments, the first connecting portion 322 and the second connecting portion 326 may be directly fixed to the board 10 by soldering to electrically connect the reactor 300 to the board 10.

In the reactor 300 according to the above embodiment, the winding 310 and the connection member 320 are formed from a single conductive member. This structure eliminates additional members such as lead wires for connecting the reactor 300 and an electronic component such as the board 10. This can reduce radiation noise at joints between the reactor 300 and components including other components such as lead wires. The connection member 320 includes spiral portions that absorb any vibrations of the board 10 or the reactor 300. This structure prevents a large load from being applied at joints between the board 10 and the connection member 320 when the board 10 or the reactor 300 vibrates. This prevents failures such as cracks at joints between the board 10 and the connection member 320 when the board 10 or the reactor 300 vibrates.

Although the present invention has been described based on the embodiments, the technical scope of the present invention is not limited to the embodiments described above. It will be apparent to those skilled in the art that variations and modifications can be made to the above embodiments. It will also be apparent from the appended claims that such variations and modifications can fall within the technical scope of the present invention.

The processing associated with the operations, procedures, steps, and phases involved in apparatuses, systems, programs, and methods described in the claims, description, and drawings may be implemented in any order unless otherwise specified using terms such as “before” or “prior to” or unless an output of one process is used in a subsequent process. The operational procedure including terms such as “first” or “subsequently” described in the claims, description, and drawings does not intend to limit the order of the procedure.

### REFERENCE SIGNS LIST

10, 20, 30 board
12 terminal block
14 screw
50 heat sink
100, 200 connection member
102, 202 spiral portion
104, 204 first connecting portion
106, 206 second connecting portion
200 connection member
300 reactor
310 winding
320 connection member
322 first connecting portion
324 first spiral portion
326 second connecting portion
328 second spiral portion
1000 board module
2000 board module

1. A reactor, comprising:
a winding;
a magnetic core included in the winding; and
a connection member extending from the winding and electrically connecting with an electronic component, the connection member being at least partially spiral between the winding and the electronic component,
wherein the winding and the connection member are formed from a single conductive member.

2. The reactor according to claim 1, wherein
the single conductive member is a single rod or a single plate.

3. The reactor according to claim 1, wherein
the electronic component is a board, and
the connection member has an end directly fixed to the board.

4. The reactor according to claim 1, wherein
the electronic component is a board, and
the connection member has an end directly fixed to a terminal block on the board.

5. The reactor according to claim 1, wherein
the connection member includes a first spiral portion that is at least partially spiral and extends from a first end of the winding, and a second spiral portion that is at least partially spiral and extends from a second end of the winding, and
a spiral of the first spiral portion and a spiral of the second spiral portion face each other.

6. The reactor according to claim 5, wherein
the spiral of the first spiral portion and the spiral of the second spiral portion have the same shape.

7. A board module, comprising:
the reactor according to claim 1; and
a board that is the electronic component electrically connected to the reactor.

8. The board module according to claim 7, wherein
the board includes a switch configured to input a pulse current into the reactor.

9. An electric device, comprising:
the board module according to claim 7; and
a housing including a first fixing member to which the reactor is fixed, and a second fixing member to which the board is fixed.

10. A connection member for electrically connecting a first electronic component and a second electronic component, the connection member being formed from a single conductive member, the connection member comprising:
a first end that is electrically connected to the first electronic component;
a second end that is electrically connected to the second electronic component; and
a spiral portion arranged between the first end and the second end.

11. The connection member according to claim 10, wherein
the conductive member is a single rod or a single plate.

12. The connection member according to claim 10, wherein
the first electronic component is a first board, and
the first end is directly fixed to the first board.

13. The connection member according to claim 10, wherein
the first electronic component is a first board, and
the first end is directly fixed to a terminal block on the first board.

14. The connection member according to claim 10, wherein
the second electronic component is a second board, and
the second end is directly fixed to the second board.

15. The connection member according to claim 10, wherein
the second electronic component is a second board, and
the second end is directly fixed to a terminal block on the second board.

16. A board module, comprising:
the connection member according to claim 10;
a first board that is the first electronic component including a first electric circuit; and
a second board that is the second electronic component including a second electric circuit electrically connected to the first electric circuit with the connection member.

17. The board module according to claim 16, wherein
at least one of the first electric circuit and the second electric circuit includes a switch, and
the connection member transmits a pulse current output from the switch between the first board and the second board.

18. The board module according to claim 16, wherein at least one of the first electric circuit and the second electric circuit includes a noise filter.

19. An electric device, comprising:
the board module according to claim 16; and
a housing including a first fixing member to which the first board is fixed, and a second fixing member to which the second board is fixed.
